(19) United States
(12) Patent Application Publication
(10) Pub. No.: US 2009/0215423 A1
(43) Pub. Date: Aug. 27, 2009

(54) MULTI-PORT CORRELATOR AND RECEIVER HAVING THE SAME

(76) Inventors: Seon-ho HWANG, Yongin-si (KR); Jae-sup Lee, Yongin-si (KR); Moo-que Lee, Seoul (KR)

Correspondence Address: MCNEELY BODENDORF LLP, P.O. BOX 34175, WASHINGTON, DC, 20043, US

(21) Appl. No.: 12/178,744

(22) Filed: Jul. 24, 2008

(30) Foreign Application Priority Data
Feb. 22, 2008 (KR) 10-2008-0016497

(51) Int. Cl. H03B 19/00; H04B 1/16

(52) U.S. Cl. 455/334; 331/45

(57) ABSTRACT

A multi-port correlator and a receiver having the same are provided. A multi-port correlator includes an oscillating unit which generates a plurality of oscillating signals having different phases, a combining unit which combines the plurality of oscillating signals respectively with a radio frequency (RF) signal and outputs a plurality of composite signals.

### CROSS REFERENCE TO RELATED APPLICATIONS

This application claims the benefit under 35 U.S.C. §119(a) of a Korean Patent Application No. 10-2008-0016497, filed on Feb. 22, 2008, in the Korean Intellectual Property Office, the disclosure of which is incorporated herein in its entirety by reference.

### TECHNICAL FIELD

The following description relates to a correlator, and more particularly, to a correlator for extracting vector information from an input signal and a receiver having the same.

### BACKGROUND

In general, a direct conversion method is a method of converting a transmission frequency into a low frequency base band. The direct conversion method may be used to construct a communication system. A structure for the direct conversion may include a mixer and a six-port correlator. The direct conversion method using a correlator may have a simple circuit structure, and accordingly, may be easily integrated.

Typically, a correlator changes the phases of high frequency signals (for example, radio frequency (RF) signals) and local oscillating signals (LO signals). In order to change the phases of RF signals and LO signals, the correlator may include a plurality of hybrid couplers. A communication system may demodulate received signals using such a correlator.

In the case of a receiver, RF signals are received through an antenna and input to a correlator, and LO signals generated by a local correlator are divided into a plurality of LO signals by a power divider and input to the correlator. A hybrid coupler included in the correlator couples the LO signals and RF signals and generates an output signal. The amplitude and phase of the output signal depends on a s parameter of the correlator. Thereafter, a signal processor analyzes a relationship between the amplitude and phase of the output signal and extracts vector information of an original RF signal from the analyzed result.

A hybrid coupler may be a distributed element, and the characteristics of the hybrid coupler may be affected by a wavelength of the hybrid coupler. Therefore, where a correlator is implemented using a hybrid coupler, there may be difficulties in integrating the entire structure of a receiver into a single IC chip under a low frequency environment. Also, it may be difficult to operate a distributed element such as a hybrid coupler under a wideband frequency environment.

### SUMMARY

In one general aspect, there is provided a multi-port correlator which is integrated into a single IC under a low frequency environment and operates in a wideband frequency environment, and a receiver having the multi-port correlator. The multi-port correlator may be implemented by using a multi-phase local oscillator having active elements.

In another general aspect, a multi-port correlator includes an oscillating unit which generates a plurality of oscillating signals having different phases, and a combining unit which combines the plurality of oscillating signals respectively with an radio frequency (RF) signal and outputs a plurality of composite signals.

The oscillating unit may be a differential oscillator. For example, the oscillating unit is a quadrature voltage-controlled oscillator (QVCO) or a ring oscillator. Also, the combining unit may be a power combiner having a differential amplifier.

The oscillating unit may comprise at least one active element.

The oscillating unit may comprise a differential oscillator having a field effect transistor (FET).

The oscillating unit may be a quadrature voltage-controlled oscillator (QVCO) in which two voltage-controlled oscillators (VCOs) having a symmetrical structure are connected to each other in a feedback loop or a ring oscillator in which a plurality of inverting amplifiers are connected in successive to each other, each inverting amplifier having a delay component.

The plurality of oscillating signals may have different relative phases of 0°, 90°, 180°, and 270°.

The plurality of oscillating signals may have different relative phases of 0°, 120°, and 240°.

The combining unit may be a differential amplifier, which receives the RF signal and the plurality of oscillating signals respectively through input terminals and combines the RF signal with the plurality of oscillating signals.

The RF signal and the plurality of oscillating signals may be input to gates of the differential amplifier, and the plurality of composite signals may be output as source voltages of the differential amplifier.

The plurality of composite signals may be capable of being processed by Quadrature Phase Shift Keying (QPSK) or Quadrature Amplitude Modulation (QAM).

In still another general aspect, a receiver includes an oscillating unit which generates a plurality of oscillating signals having different phases, a combining unit which combines the plurality of oscillating signals respectively with an radio frequency (RF) signal and outputs a plurality of composite signals, a detecting unit which detects power of the plurality of composite signals, and a demodulating unit which demodulates the RF signal using the detected power.

The oscillating unit may comprise at least one active element.

The detecting unit may comprise a schottky diode which detects the power of the plurality of composite signals, and a low pass filter (LPF) which removes a high frequency signal.

The demodulating unit may analyze the composite signals and process the composite signals using a Quadrature Phase Shift Keying (QPSK) or Quadrature Amplitude Modulation (QAM) method.

The oscillating signals generated by the oscillating unit may be four signals having different relative phases of 0°, 90°, 180°, and 270°, or three signals having different relative phases of 0°, 120°, and 240°.

The plurality of composite signals may be four signals whose phase differences are 90° to each other, and the demodulating unit may generate an I channel signal and a Q channel signal by demodulating the plurality of composite signals using Quadrature Phase Shift Keying (QPSK).

Other features will become apparent to those skilled in the art from the following detailed description, which, taken in conjunction with the attached drawings, discloses exemplary embodiments of the invention.

### BRIEF DESCRIPTION OF THE DRAWINGS

FIG. 1 is a configuration diagram illustrating a multi-port correlator according to an exemplary embodiment.

FIG. 2 is a diagram illustrating a structure an oscillator according to an exemplary embodiment.

FIG. 3 is a circuit diagram illustrating an oscillator according to an exemplary embodiment.

FIG. 4 is a circuit diagram illustrating an oscillator according to another exemplary embodiment.

FIGS. 5 and 6 are diagrams illustrating a structure of a combiner according to an exemplary embodiment.

FIG. 7 is a configuration diagram illustrating a structure of a receiver having a multi-port correlator, according to an exemplary embodiment.

Throughout the drawings and the detailed description, unless otherwise described, the same drawing reference numerals will be understood to refer to the same elements, features, and structures. The elements may be exaggerated for clarity and convenience.

### DETAILED DESCRIPTION

The following detailed description is provided to assist the reader in gaining a comprehensive understanding of the media, apparatuses, methods and/or systems described herein. Accordingly, various changes, modifications, and equivalents of the systems, methods, apparatuses and/or media described herein will be suggested to those of ordinary skill in the art. Also, description of well-known functions and constructions are omitted to increase clarity and conciseness.

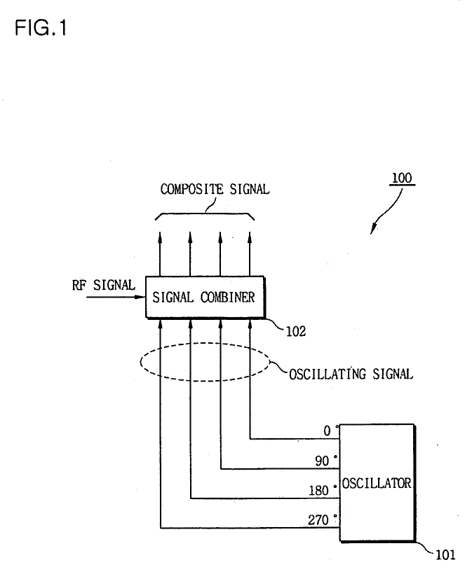

FIG. 1 illustrates a structure of a multi-port correlator 100 according to an exemplary embodiment.

The multi-port correlator 100 of FIG. 1 may be used to analyze vector information of an input RF signal. For example, the multi-port correlator 100 is may be used in a transceiver in which a transmitter and a receiver are integrated into a single body, to modulate or demodulate RF signals. In order to analyze vector information of an RF signal, a processing an RF signal using various methods, including a process of changing a phase of the RF signal, may be required. FIG. 1 illustrates an example where an RF signal is converted into four composite signals by the multi-port correlator 100.

Oscillating signals generated by an oscillator 101 are respectively combined with an RF signal received from another input source (not shown) by a combiner 102, and then output as composite signals. The oscillator 101 may generate four oscillating signals, and each oscillating signal is combined with the RF signal in the combiner 102.

The oscillator 101 may generate a plurality of the oscillating signals having the same frequency but with different phases. For example, the oscillator 101 may generate four oscillating signals having the same frequency, and the oscillating signals may have different relative phases of 0°, 90°, 180°, and 270°. In another example, the oscillator 101 may generate three oscillating signals having the same frequency, and the oscillating signals may have different relative phases of 0°, 120°, and 240°.

It is understood that the oscillator 101, which generates a plurality of oscillating signals having different phases, may be implemented by various methods. For example, oscillating signals generated by a local oscillator may be divided according to phase differences by using a hybrid coupler which is a distributed element. However, since the pattern size of a device may increase in a low frequency environment where a distributed element is utilized, an active element such as a field effect transistor (FET) may be utilized. According to an exemplary embodiment, the oscillator 101 constructed using an active element may be a quadrature voltage-controlled oscillator (QVCO) in which two voltage controlled oscillators (VCOs) are connected to each other in a feedback loop, or a ring oscillator in which a plurality of inverting amplifiers are connected in series to each other. The oscillator 101 may also be implemented using an RF multi-phase filter and a frequency divider, for generating oscillating signals having multi-phases.

The oscillating signals generated by the oscillator 101 are respectively combined with an RF signal in the combiner 102. For example, the combiner 102 is a power combiner that combines the oscillating signals with the RF signal and outputs a plurality of composite signals. The term “a composite signal” means a combination signal of an RF signal and an oscillating signal.

It may be assumed that where amplitudes and frequencies of the RF signal and the oscillating signals are the same, the phase differences between the composite signals are the same as the phase differences between the oscillating signals generated by the oscillator 101. For example, where the phase differences between the oscillating signals are 90° to each other, the phase differences between the composite signals is also 90° to each other. Accordingly, where the RF signal is a signal modulated by a QPSK method and the oscillator 101 generates four oscillating signals whose phase differences are 90° to each other, the multi-port correlator 100 may be used as a demodulation module which extracts I/Q data in a receiver of a wireless communication system.

Since the oscillator 101 is implemented using an active element according to an exemplary embodiment, the number and phase of oscillating signals may be controlled using an external voltage or current. Accordingly, the oscillator 101 may be applied in various ways in a transmitter or receiver of a communication device by adjusting the number and phase of oscillating signals. The number and phase of oscillating signals may be varied according to modulation methods.

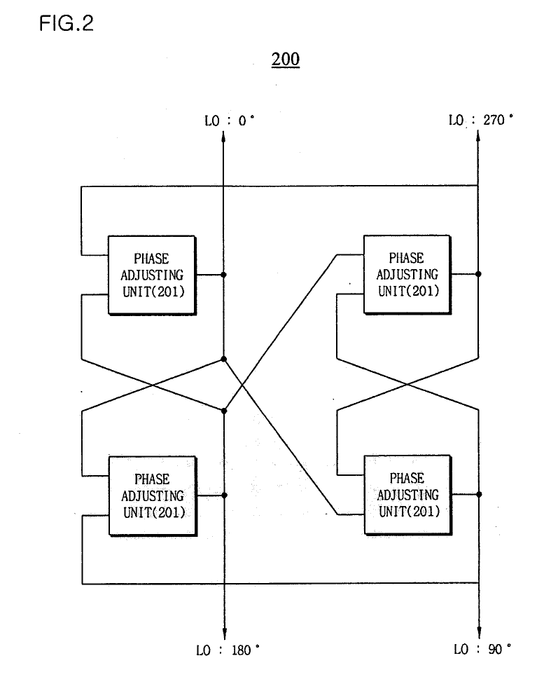

FIG. 2 illustrates an oscillator 200 according to an exemplary embodiment.

Referring to FIG. 2, the oscillator 200 comprises four phase adjusting units 201, and a plurality of oscillating signals having different phases are output from the output terminals of the phase adjusting units 201. Each phase adjusting unit 201 may be implemented using a transconductor which is controlled by a voltage. For example, each phase adjusting unit 201 may be implemented by a differential amplifier or an inverter, and the phase of a signal input to the phase adjusting unit 201 may be changed by adjusting a bias voltage that is to be applied to the differential amplifier or inverter.

As illustrated in FIG. 2, the phase adjusting units 201 for adjusting the phases of input signals are arranged in such a manner that the output of one phase adjusting unit 201 is input to an input terminal of another phase adjusting unit 201 to delay a signal passing through the phase adjusting unit 201 or invert the phase of the signal, so as to generate a plurality of oscillating signals having different phases. In FIG. 2, the phase differences of the generated oscillating signals are 90° to each other. However, the phase differences of the generated oscillating signals are not limited to this, and the phase differences of the oscillating signals may be set to various values by appropriately adjusting the differential amplifier or inverter included in the phase adjusting units 201.

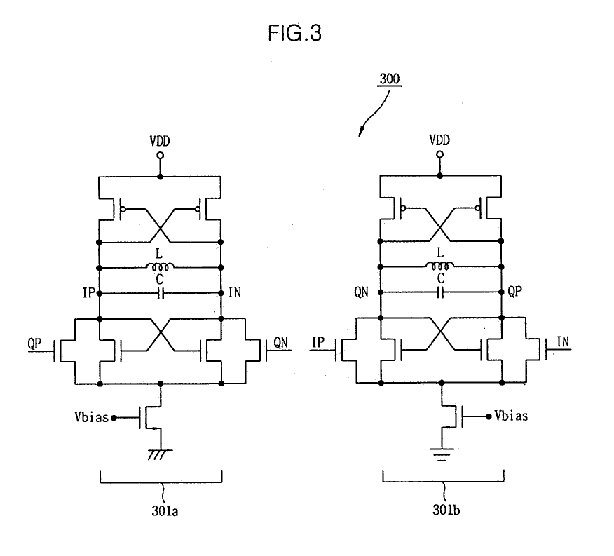

FIG. 3 illustrates a circuit diagram of an oscillator 300 according to an exemplary embodiment.

As shown in FIG. 3, the oscillator 300 is implemented using a differential oscillator including FETs which are active elements. Referring to FIG. 3, the oscillator 300 comprises two VCOs 301a and 301b. Each VCO 301a or 301b includes an inductor L and a capacitor C for establishing an oscillating frequency, and a plurality of FETs for providing negative resistance and coupling. The VCOs 301a and 301b may have a symmetrical structure, and may construct a quadrature voltage-controlled oscillator (QVCO) in such a manner that the input and output of the VCOs 301a and 301b are connected to each other in a feedback loop.

One (for example, the VCO 301a) of the two VCOs 301a and 301b outputs a positive in-phase signal IP and a negative in-phase signal IN, and the other (for example, the VCO 301b) outputs a negative quadrature-phase signal QN and a positive quadrature-phase signal QP. Accordingly, since the phase differences of the output signals of the VCO 301a and 301b are 90° to each other, where the oscillator 101 of the multi-port correlator 100 of FIG. 1 is constructed using the QVCO 300 illustrated in FIG. 3, the output signals may be used as oscillating signals.

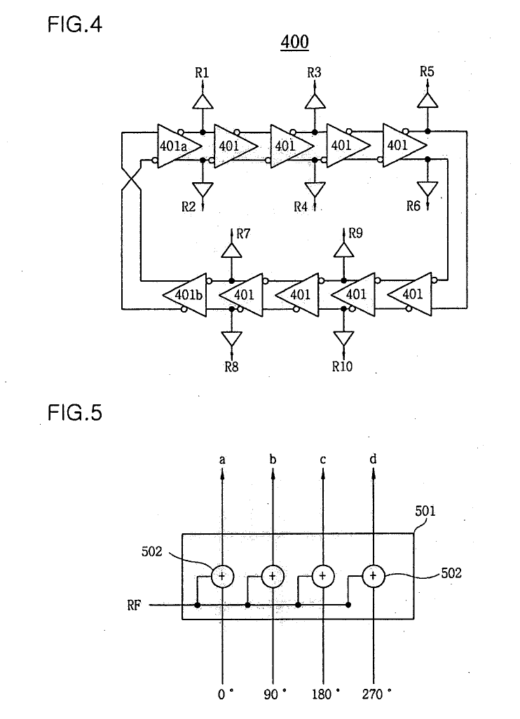

FIG. 4 illustrates a circuit diagram of an oscillator 400 according to another exemplary embodiment.

Referring to FIG. 4, the oscillator 400 has a structure similar to a ring oscillator, in which a plurality of inverting amplifiers are connected in series to each other in the form of a ring.

Each inverting amplifier 401 amplifies a difference between a signal received through a non-inverting terminal and a signal received through an inverting terminal, and outputs a differential signal corresponding to the amplified result. Each inverting amplifier 401 includes its own delay component. Accordingly, a signal passing through each inverting amplifier 401 is delayed, and thus the phase of the signal is inverted. Also, since the inverting output terminal of a final inverting amplifier 401b is connected to the inverting input terminal of the first inverting amplifier 401a, the phase of a signal is inverted after once passing through the ring structure.

The delay component of each inverting amplifier 401 may be adjusted by a voltage or current applied to the inverting amplifier 401. Since oscillating signals R1-R10 which have passed through the inverting amplifiers 401 have difference phases, the oscillating signals R1-R10 may be used as the oscillating signals described above in, for example, FIG. 1.

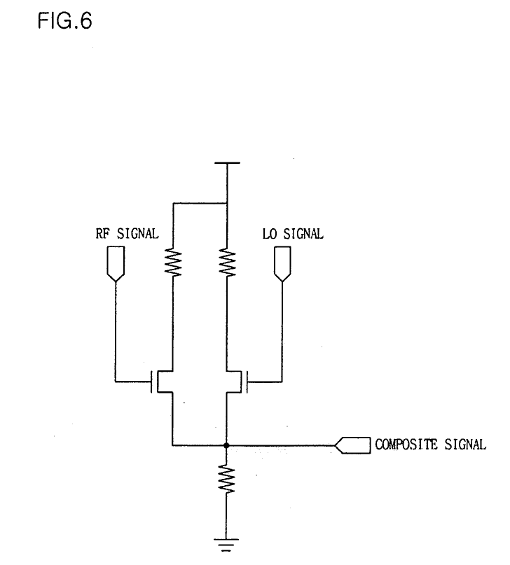

FIG. 5 illustrates a circuit diagram of a combiner 501 according to an exemplary embodiment.

Referring to FIG. 5, an RF signal and oscillating signals having different relative phases of 0°, 90°, 180°, and 270° are input to and added in the combiner 501, and then output as composite signals a through d. The combiner 501 may include a plurality of adders 502, each located at a path through which an oscillating signal passes. For example, where four oscillating signals having phase differences which are 90° to each other are applied to the combiner 501, four adders 502 may be provided in correspondence with the number of the oscillating signals. The phases of RF signals input to the adders 502 may be all 0°. Accordingly, the composite signals (denoted by a, b, c, and d) may be expressed as below.

a=RF∠0+L0∠0

b=RF∠0+L0∠90

c=RF∠0+L0∠180

d=RF∠0+L0∠270

In the above equations, RF represents the amplitude of the RF signal, L0 represents the amplitude of the oscillating signal, and ∠ represents the phase of the corresponding signal. By utilizing the combiner 501, the phase differences of the oscillating signals may be maintained at a specific oscillating frequency and the oscillating signals may be combined with the RF signal. Also, the composite signals have phase differences which are 90° to each other, like the oscillating signals.

Where voltages detected from the composite signals a through d passing through the combiner 501 are plotted in the form of a constellation diagram, the coordinates of the composite signals a through d have phase difference which are 90° to each other. Accordingly, the composite signals a through d may be processed by the QPSK or QAM method where they are modulated or demodulated.

Each adder 502 may be implemented using a differential amplifier. An RF signal and oscillating signals may be input to gate terminals of the differential amplifier. For example, as illustrated in FIG. 6, the adder 502 of FIG. 5 may be implemented by using a phenomenon in which a source voltage increases in a common mode by utilizing a differential amplifier.

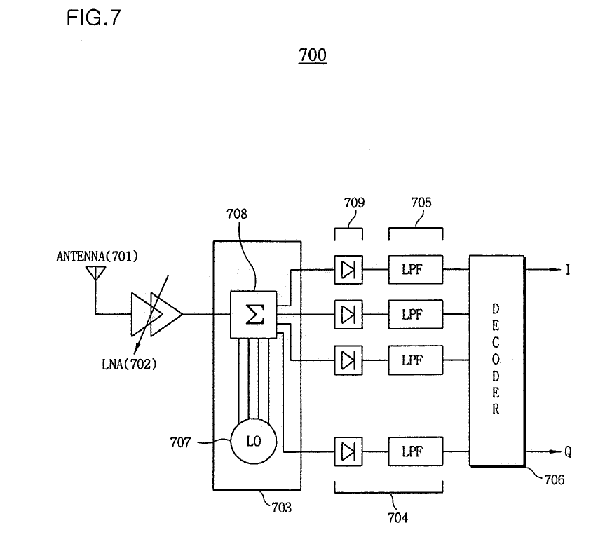

FIG. 7 illustrates a receiver 700 having a multi-port correlator according to an exemplary embodiment.

Referring to FIG. 7, an antenna 701 receives an RF signal transmitted from a transmitter of a wireless communication system. The RF signal received through the antenna 701 may have a very low power level due to attenuation or noise because the RF signal is subjected to various external environments. A low noise amplifier 702 amplifies the RF signal while minimizing noise of the RF signal. A correlator 703 changes a phase of the RF signal which has passed through the low noise amplifier 702, and extracts vector information from the RF signal. The correlator 703 may include an oscillator 707 which generates a plurality of oscillating signals having different phases, and a combiner 708 which combines the oscillating signals with an RF signal. For example, where four oscillating signals are generated by the oscillator 707 and the phase differences of the oscillating signals are 90° to each other, the oscillating signals may be expressed as follows.

α=L0∠0

β=L0∠90

γ=L0∠180

δ=L0∠270

In the above equations, α, β, γ, and δ represent the oscillating signals generated by the oscillator 707, L0 represents the amplitude of the corresponding oscillating signal, and ∠ represents the phase of the corresponding oscillating signal.

The oscillating signals may be generated by a QVCO or a ring oscillator, and the configuration described above with reference to FIGS. 2 through 4 may be applied to the oscillator 707.

The oscillating signals α, β, γ, and δ are respectively combined with the RF signal in the combiner 708, and the combiner 708 may have the construction described above with reference to FIG. 5. Accordingly, the RF signal which has passed through the correlator 703 may be divided into four signals while maintaining the phase differences of the oscillating signals. That is, four composite signals are output through the correlator 703, and the phase differences of the composite signals are 90° to each other, like the oscillating signals.

The composite signals are input to a detector 704, and the detector 704 detects power of the composite signals using a square-law detector 709. The square-law detector 709 may be a schottky diode or a power detector. Also, the detector 704 may include a low pass filter 705 to remove high frequency components from the composite signals. The output of the detector 704 is input to a demodulator 706, and the demodulator 706 demodulates the RF signal using the output value of the detector 704, that is, using the power of the composite signals.

For example, where the RF signal is a signal modulated by the QPSK method, the output of the detector 704 may be expressed according to the I/Q value of the RF signal, below.

TABLE 1

| | PD0 | PD1 | PD2 | PD3 |
|---|---|---|---|---|
| 11 | −1 | 0 | 1 | 0 |
| 10 | 0 | 1 | 0 | −1 |
| 01 | 0 | −1 | 0 | 1 |
| 00 | 1 | 0 | −1 | 0 |

In Table 1, PD0 through PD3 refer to the respective output ports of the detector 704. Where the output of the detector 704, as shown in Table 1, is input to the demodulator 706, the demodulator 706 determines I/Q data of the RF signal. Such signal restoration may be easily performed by installing a comparator in the demodulator 706.

In FIG. 7, an multi-port correlator according to an exemplary embodiment is applied to a receiver of a communication system. However, it is understood that a multi-port correlator consistent with the disclosure herein may have various other applications, including an application in which vector information of an RF signal is extracted and used. As a non-limiting illustration, a multi-port correlator consistent with the instant disclosure may be applied to a frontend of a software defined radio (SDR) terminal, a transceiver, various sensors, and a vector analysis device of a radar.

A number of exemplary embodiments have been described above. Nevertheless, it will be understood that various modifications may be made. For example, suitable results may be achieved if the described techniques are performed in a different order and/or if components in a described system, architecture, device, or circuit are composite in a different manner and/or replaced or supplemented by other components or their equivalents. Accordingly, other implementations are within the scope of the following claims.

What is claimed is:

1. A multi-port correlator comprising:
an oscillating unit which generate a plurality of oscillating signals having different phases; and
a combining unit which combines the plurality of oscillating signals respectively with an radio frequency (RF) signal and outputs a plurality of composite signals.

2. The multi-port correlator of claim 1, wherein the oscillating unit comprises a differential oscillator having a field effect transistor (FET).

3. The multi-port correlator of claim 1, wherein the oscillating unit is a quadrature voltage-controlled oscillator (QVCO) in which two voltage-controlled oscillators (VCOs) having a symmetrical structure are connected to each other in a feedback loop.

4. The multi-port correlator of claim 1, wherein the oscillating unit is a ring oscillator in which a plurality of inverting amplifiers are connected in series to each other, each inverting amplifier having a delay component.

5. The multi-port correlator of claim 1, wherein the plurality of oscillating signals have different relative phases of 0°, 90°, 180°, and 270°.

6. The multi-port correlator of claim 1, wherein the plurality of oscillating signals have different relative phases of 0, 120°, and 240°.

7. The multi-port correlator of claim 1, wherein the combining unit is a differential amplifier, which receives the RF signal and the plurality of oscillating signals respectively through input terminals and combines the RF signal with the plurality of oscillating signals.

8. The multi-port correlator of claim 7, wherein the RF signal and the plurality of oscillating signals are input to gates of the differential amplifier, and the plurality of composite signals are output as source voltages of the differential amplifier.

9. The multi-port correlator of claim 1, wherein the plurality of composite signals are capable of being processed by Quadrature Phase Shift Keying (QPSK) or Quadrature Amplitude Modulation (QAM).

10. The multi-port correlator of claim 1, wherein the oscillating unit comprises at least one active element.

11. A receiver comprising:
an oscillating unit which generates a plurality of oscillating signals having different phases;
a combining unit which combines the plurality of oscillating signals respectively with an radio frequency (RF) signal and outputs a plurality of composite signals;
a detecting unit which detects power of the plurality of the composite signals; and
a demodulating unit which demodulates the RF signal using the detected power.

12. The receiver of claim 11, wherein the oscillating unit comprises a differential oscillator having a field effect transistor (FET).

13. The receiver of claim 11, wherein the oscillating unit is a quadrature voltage-controlled oscillator (QVCO) in which two voltage-controlled oscillators (VCOs) having a symmetrical structure are connected to each other in a feedback loop.

14. The receiver of claim 11, wherein the oscillating unit is a ring oscillator in which a plurality of inverting amplifiers are connected in series to each other, each inverting amplifier having a delay component.

15. The receiver of claim 11, wherein the detecting unit comprises:
a schottky diode which detects the power of the plurality of composite signals; and
a low pass filter (LPF) which removes a high frequency signal.

16. The receiver of claim 11, wherein the plurality of oscillating signals have different relative phases of 0°, 90°, 180°, and 270°.

17. The receiver of claim 11, wherein the plurality of composite signals are four signals whose phase differences are 90° to each other, and the demodulating unit generates an I channel signal and a Q channel signal by demodulating the plurality of composite signals using Quadrature Phase Shift Keying (QPSK).

18. The receiver of claim 11, wherein the oscillating unit comprises at least one active element.
